(19) United States
(12) Patent Application Publication
(10) Pub. No.: US 2025/0062256 A1
(43) Pub. Date: Feb. 20, 2025

(54) SIGNAL TRANSMISSION DEVICE

(71) Applicant: DENSO CORPORATION, Kariya-city. (JP)

(72) Inventors: Shuji ASANO, Kariya-city (JP); Koichi YAKO, Kariya-city (JP)

(21) Appl. No.: 18/939,129

(22) Filed: Nov. 6, 2024

Related U.S. Application Data
(63) Continuation of application No. PCT/JP2023/016316, filed on Apr. 25, 2023.

(30) Foreign Application Priority Data
May 11, 2022 (JP) 2022-078433

(51) Int. Cl. H01L 23/00; H01L 23/31; H01L 23/522

(52) U.S. Cl. CPC H01L 24/05; H01L 23/3192; H01L 23/5223; H01L 23/5225; H01L 28/60; H01L 2224/0219; H01L 2224/05551; H01L 2224/05567

(57) ABSTRACT

A signal transmission device having a capacitor coupler includes: a semiconductor substrate; a first insulating film disposed above the semiconductor substrate; a lower electrode disposed above the semiconductor substrate across a portion of the first insulating film; an upper electrode disposed opposite the lower electrode across the first insulating film, forming a capacitor together with the lower electrode, and configured to be applied with a voltage higher than a voltage applied to the lower electrode; a second insulating film disposed above the first insulating film and covering at least a portion in an outer peripheral portion of the upper electrode that is in contact with the first insulating film; and a third insulating film disposed above the second insulating film and made of an insulating organic material. The second insulating film is made of a material having a higher insulation breakdown voltage than the third insulating film.

### CROSS REFERENCE TO RELATED APPLICATIONS

The present application is a continuation application of International Patent Application No. PCT/JP2023/016316 filed on Apr. 25, 2023, which designated the U.S. and claims the benefit of priority from Japanese Patent Application No. 2022-078433 filed on May 11, 2022. The entire disclosures of all of the above applications are incorporated herein by reference.

### TECHNICAL FIELD

The present disclosure relates to a signal transmission device having a capacitor coupler.

### BACKGROUND

Conventionally, there has been known a signal transmission device that has a capacitor coupler electrically isolating and separating a high voltage circuit and a low voltage circuit and configured to transmit a signal between the high voltage circuit and the low voltage circuit.

### SUMMARY

The present disclosure provides a signal transmission device having a capacitor coupler, and the signal transmission device includes: a semiconductor substrate; a first insulating film disposed above the semiconductor substrate; a lower electrode disposed above the semiconductor substrate across a portion of the first insulating film; an upper electrode disposed opposite the lower electrode across the first insulating film, forming a capacitor together with the lower electrode, and configured to be applied with a voltage higher than a voltage applied to the lower electrode; a second insulating film disposed above the first insulating film and covering at least a portion in an outer peripheral portion of the upper electrode that is in contact with the first insulating film; and a third insulating film disposed above the second insulating film and made of an insulating organic material. The second insulating film is made of a material having a higher insulation breakdown voltage than the third insulating film.

### BRIEF DESCRIPTION OF DRAWINGS

Objects, features and advantages of the present disclosure will become apparent from the following detailed description made with reference to the accompanying drawings. In the drawings:

FIG. 1 is a partial cross-sectional view of a signal transmission device having a capacitor coupler according to a first embodiment;

FIG. 2 is a diagram showing the capacitor coupler of FIG. 1 as viewed from above;

FIG. 3 is an enlarged cross-sectional view of area III in FIG. 1;

FIG. 4 is a diagram showing the results of investigating how an electric field is applied near a capacitor coupler in a comparative example in which an end portion of an upper electrode of the capacitor coupler is covered with a material with low insulation breakdown voltage;

FIG. 5 is a diagram showing a state of an insulation breakdown in the comparative example of FIG. 4;

FIG. 6 is a diagram showing the results of investing how an electric field is applied near the capacitor coupler in the signal transmission device of the first embodiment;

FIG. 7 is a partial cross-sectional view of a signal transmission device according to a second embodiment;

FIG. 8 is a diagram showing another example of shapes of an upper electrode and a lower electrode of a capacitor coupler; and

FIG. 9 is a partial cross-sectional view showing a signal transmission device according to another embodiment.

### DETAILED DESCRIPTION

Next, a relevant technology is described only for understanding the following embodiments. A signal transmission device according to the relevant technology includes a capacitor coupler configured with a lower electrode applied with a low voltage, an upper electrode applied with a high voltage, and an insulating film interposed between the lower electrode and the upper electrode. The signal transmission device includes a shield portion in which conductive vias and conductive interconnect structures are alternately and repeatedly stacked in multiple stages between the capacitor coupler and peripheral elements provided around the capacitor coupler so that application of a high electric field to the peripheral elements is restricted.

When the signal transmission device having the capacitor coupler is used for, for example, on-off control of a power switching element that controls a high voltage drive motor or the like, a high electric field of 1 kVrms is applied between the upper electrode and the lower electrode. When the high electric field is applied between the upper electrode and the lower electrode, the high electric field is also applied around the capacitor coupler. The signal transmission device has a structure in which an outer peripheral portion of the upper electrode, which is located outside a portion to which a wire is connected, is covered with an insulating film that is thicker than a thickness of the upper electrode, and a high electric field portion around the upper electrode is embedded in the insulating film.

A structure in which the outer peripheral portion of the upper electrode is covered with a thick insulating film made of silicon nitride or the like, as in the above-described signal transmission device, can be formed, for example, by processes of laminating and thickening the insulating film, planarizing the insulating film by chemical mechanical polishing (CMP), and forming an opening portion in the insulating film by etching. However, this structure requires a long time for the process of thickening the insulating film and the process of etching, which is one of factors that increase a manufacturing cost of the signal transmission device.

Therefore, from the viewpoint of improving throughput and costs in manufacture of signal transmission devices to which high voltages are applied, the present inventors conducted diligent study on a structure in which the insulating film covering the upper electrode is made of an insulating organic material, such as polyimide, that can be formed by coating. As a result of the diligent study, the present inventors found that, in a signal transmission device with such a structure, an insulation breakdown may occur at a part of the insulating film in contact with the high electric field portion.

A signal transmission device according to an aspect of the present disclosure has a capacitor coupler, and includes: a semiconductor substrate; a first insulating film disposed above the semiconductor substrate; a lower electrode disposed above the semiconductor substrate across a portion of the first insulating film; an upper electrode disposed opposite the lower electrode across the first insulating film, forming a capacitor together with the lower electrode, and configured to be applied with a voltage higher than a voltage applied to the lower electrode; a second insulating film disposed above the first insulating film and covering at least a portion in an outer peripheral portion of the upper electrode that is in contact with the first insulating film; and a third insulating film disposed above the second insulating film and made of an insulating organic material. The second insulating film is made of a material having a higher insulation breakdown voltage than the third insulating film.

In the signal transmission device, at least the portion in the outer peripheral portion of the upper electrode that is in contact with the first insulating film is covered with the second insulating film, and the second insulating film is covered with the third insulating film made of the insulating organic material. The second insulating film is made of the material having the higher insulation breakdown voltage than the third insulating film. Therefore, when a high voltage of, for example, 1 kVrms or more is applied to the upper electrode, an electric field concentration portion generated in the vicinity of the upper electrode is covered with the second insulating film, and an insulation breakdown in the third insulating film made of the insulating organic material is restricted. Furthermore, since the signal transmission device includes the third insulating film made of the insulating organic material laminated on the second insulating film, a process of forming the insulating film that covers a part of the upper electrode is simplified. Thus, a manufacturing throughput of the signal transmission device can be improved, and a manufacturing cost of the signal transmission device can be reduced.

The following describes embodiments of the present disclosure with reference to the drawings. In the following embodiments, the same or equivalent parts are denoted by the same reference numerals.

### First Embodiment

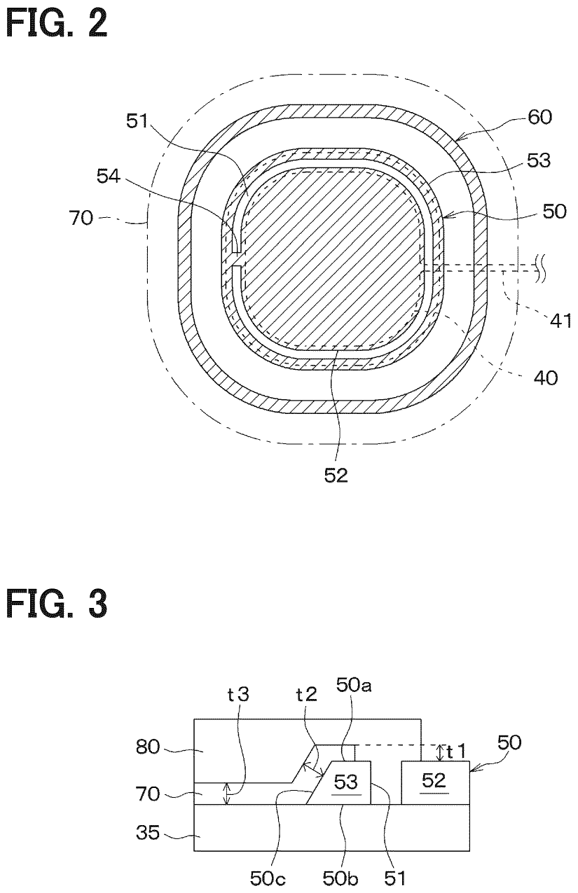

A signal transmission device having a capacitor coupler according to a first embodiment will be described with reference to the drawings. In FIG. 2, an outer periphery of a lower electrode 40 described later is shown by a dashed line, and an outer periphery of a second insulating film 70 described later is shown by a dashed-dotted line. In addition, components of an upper electrode 50 and a shield portion 60 described later are hatched although they are not indicate cross sections.

The signal transmission device of the present embodiment is used, for example, to control a power switching element used to drive a motor or the like, and has a configuration in which a capacitor coupler is integrated on a single chip together with a low voltage control circuit or a high voltage control circuit. For example, a low voltage chip on which the low voltage control circuit, the capacitor coupler, and the like are formed is configured as a separate chip from a high voltage chip on which the high voltage control circuit, the capacitor coupler, a drive circuit for the power switching element, and the like are formed. The low voltage chip and the high voltage chip have their respective capacitor couplers connected to each other, and when a signal is output from the low voltage control circuit, the signal is transmitted through the capacitor couplers. The power switching element is controlled based on the above-described signal transmission through the drive circuit provided on the high voltage chip.

In the following description, the capacitor coupler formed on the low voltage chip will be used as an example, but the capacitor coupler formed on the high voltage chip can also have the same structure as the capacitor coupler on the low voltage chip.

### [Basic Configuration]

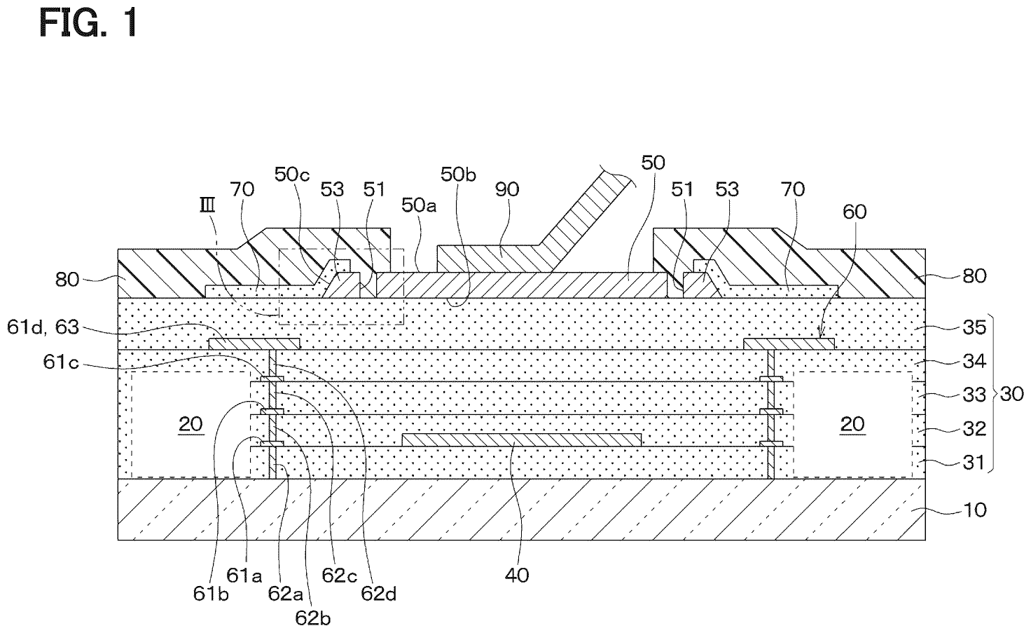

As shown in FIG. 1, the signal transmission device of the present embodiment has a low voltage circuit region 20 in a semiconductor substrate 10, and also has a capacitor coupler formed of the lower electrode 40 and the upper electrode 50 via a first insulating film 30. The signal transmission device further includes the shield portion 60 that is disposed between the lower electrode 40 and the upper electrode 50 and the low voltage circuit region 20 to separate them. Furthermore, the signal transmission device includes the second insulating film 70 and a third insulating film 80. The second insulating film 70 is disposed above the first insulating film 30 and covers an outer periphery of the upper electrode 50. The third insulating film 80 is laminated on the second insulating film 70.

The semiconductor substrate 10 is made of, for example, a silicon substrate, and peripheral elements included in the low voltage circuit region 20, such as metal oxide semiconductor field effect transistors (MOSFETs), are fabricated thereon.

The low voltage circuit region 20 is a region in which a control circuit for controlling a drive target on a high voltage side, such as the power switching element and the drive circuit for the power switching element, is formed. The control circuit provided in the low voltage circuit region 20 is driven using a low reference voltage, for example, a ground potential (hereinafter referred to as GND) as a reference. In the low voltage circuit region 20, for example, the peripheral elements are fabricated by performing a semiconductor manufacturing process on the semiconductor substrate 10, and wiring portions connected to the peripheral elements are patterned in the first insulating film 30, thereby forming an integrated circuit. The peripheral elements that constitute the control circuit include a memory, and the like, which are not shown. When the signal transmission device is shipped, data is written by injecting negative charge into the memory, and the signal transmission device is adjusted to perform the desired operation.

The first insulating film 30 has a stacked structure of multiple layers. Here, a case where the first insulating film 30 is configured as a five-layer structure including a first film 3, a second film 32, a third film 33, a fourth film 34, and a fifth film 35 will be described as a representative example, but the number of layers may be set optionally. The first film 31 is disposed on a surface of the semiconductor substrate 10, and the lower electrode 40 is disposed above the first film 31. The second film 32 to the fifth film 35 are disposed between the lower electrode 40 and the upper electrode 50, and are stacked in order on the first film 31.

The first film 31 to the fifth film 35 are made of, for example, the same insulating material, but may be made of different materials. For example, the first film 31 to the fifth film 35 are made of tetraethoxysilane (TEOS).

The thicknesses of the first film 31 to the fifth film 35 may be set optionally, but the thicknesses of the second film 32 to the fifth film 35 are appropriately determined depending on the distance between the lower electrode 40 and the upper electrode 50. In the present embodiment, the thicknesses of the first film 31 to the fourth film 34 are determined appropriately depending on the height of the shield portion 60.

The total thickness of the second film 32 to the fifth film 35 is the height from the lower electrode 40 to the upper electrode 50, with the direction in which the lower electrode 40 and the upper electrode 50 are stacked being the height direction. The total thickness of the second film 32 to the fifth film 35 determines a capacitance value of the capacitor configured with the lower electrode 40 and the upper electrode 50. Therefore, the thicknesses of the second film 32 to the fifth film 35 are determined depending on the required capacitance value. For example, the thicknesses of the second film 32 to the fifth film 35 are set so that the distance between the lower electrode 40 and the upper electrode 50 is 4 μm to 10 μm, preferably 5 μm to 8 μm.

Further, the first film 31 to the fourth film 34 are alternately and repeatedly formed with conductors 61a to 61d, which will be described later, forming the shield portion 60. In the case of the present embodiment, the total thickness of the first film 31 to the fourth film 34 is the height of the shield portion 60. The thickness of each of the first film 31 to the fourth film 34 is set to a thickness that allows the vias 62a to 62d, which constitute the shield portion 60 together with the conductors 61a to 61d, to be satisfactorily embedded.

The lower electrode 40 is one electrode of the capacitor that constitutes the capacitor coupler. The lower electrode 40 is formed above the first film 31, and is electrically connected to a desired part in the control circuit through a lead wire 41 shown in FIG. 2, which is also formed on the first film 31. By outputting a signal from the control circuit to the lower electrode 40, a signal transmission is performed between the lower electrode 40 and the upper electrode 50. Since the lower electrode 40 receives a control signal from the control circuit that operates based on a low reference voltage, a low voltage is applied thereto.

The lower electrode 40 is formed in, for example, as shown in FIG. 2, an approximate quadrangle shape with rounded corners and sides of 50 μm to 600 μm. The lower electrode 40 has a thickness of 0.2 μm to 1 μm. The constituent material of the lower electrode 40 may be any metal that is used as an electrode material, such as Al (aluminum), W (tungsten), Cu (copper), Ti (titanium), Ta (tantalum), or the like.

The upper electrode 50 is formed in, for example, as shown in FIG. 2, an approximate quadrangle shape with rounded corners and sides of 50 μm to 600 μm. From the viewpoint of ensuring bondability when joining wiring materials such as a wire 90, the upper electrode 50 is preferably configured to have a thickness of, for example, 3.0 μm or more. The upper electrode 50 is formed on the lower electrode 40 via the second film 32 to the fifth film 35. As shown in FIG. 1 and FIG. 2, for example, the upper electrode 50 has a slit 51 formed near an outer periphery and along the outer periphery. The slit 51 is formed to reduce stress in the second insulating film 70, which will be described later, and is filled with a part of the third insulating film 80 in the present embodiment. The slit 51 is formed, for example, by forming an approximately quadrangle metal film constituting the upper electrode 50 on the first insulating film 30, and then partially removing the metal film by photolithography etching.

For ease of explanation, a portion of the upper electrode 50 inside the slit 51 will be referred to as an electrode portion 52, and a portion outside the slit 51 will be referred to as an outer frame portion 53. FIG. 2 shows one surface of the semiconductor substrate 10 on which the first insulating film 30 and the electrodes 40 and 50 are formed, as viewed from the normal direction to the surface. In the following description, a state viewed from the normal direction may be referred to as a top view.

The upper electrode 50 is disposed opposite the lower electrode 40 in the top view shown in FIG. 2. When viewed from the normal direction to an upper surface 50a of the upper electrode 50, that is, when viewed from above, the electrode portion 52 of the upper electrode 50 preferably has a planar size such that an outer periphery of the electrode portion 52 is located outside the outer periphery of the lower electrode 40. Accordingly, distances between the corners of the electrode portion 52 and the outer frame portion 53 and the corners of the lower electrode 40 when viewed from above increase, making it possible to reduce the electric field concentration at the corners of the electrode portion 52 and the outer frame portion 53, as described below. The outer frame portion 53 is, for example, connected to the electrode portion 52 via a connection portion 54 and is at a potential equal to a potential of the electrode portion 52. The outer frame portion 53 may be configured so that the upper electrode 50 does not have the connection portion 54 and is independent from the electrode portion 52. In this case, the outer frame portion 53 has a different potential from the electrode portion 52 and is in a floating state in which the outer frame portion 53 is not connected to another power source or the like.

In addition, it is preferable that each side of the approximate quadrangle formed by the electrode portion 52 of the upper electrode 50 is arranged parallel to each side of the approximate quadrangle formed by the lower electrode 40, and that the center position of the electrode portion 52 and the center position of the lower electrode 40 substantially coincide with each other. However, the present disclosure is not limited to this arrangement. The upper electrode 50 may be made of any metal material or alloy material that can be used as an electrode material, such as Al, W, Cu, Ti, or Ta. The upper electrode 50 may be made of the same material as the lower electrode 40, or may be made of a different material.

The upper electrode 50 has the upper surface 50a on the side opposite the first insulating film 30 and has a lower surface 50b on the side opposite the upper surface 50a. The upper surface 50a of the electrode portion 52 is exposed from the second insulating film 70 and the third insulating film 80, allowing the wire 90 to be connected to the electrode portion 52. The upper electrode 50 is electrically connected to a chip equipped with a drive circuit for an external power switching element by connecting the wire 90 made of a conductive material such as Au (gold) to the electrode portion 52. Since the upper electrode 50 is connected to the drive circuit or the like that operates at a reference voltage higher than the low voltage referenced by the low voltage circuit region 20, a high voltage is applied to the upper electrode 50. In the upper electrode 50, a voltage of, for example, 400 Vrms or more is applied to the electrode portion 52 in the operating state.

The shield portion 60 is formed at least within the first insulating film 30. The shield portion 60 is disposed is for restricting the influence of the high electric field applied to the capacitor coupler on the peripheral elements disposed in the low voltage circuit region 20. The shield portion 60 is connected to a voltage applied during control circuit operation from low voltage, for example, the reference potential point of the low voltage circuit region 20, here the GND potential point which is the potential of the semiconductor substrate 10. In the present embodiment, for example, as shown in FIG. 2, the shield portion 60 is disposed so as to completely surround the peripheries of the lower electrode 40 and the upper electrode 50 that constitute the capacitor coupler and has a frame shape when viewed from above.

The shield portion 60 includes, for example, conductors 61a, 61b, 61c and 61d and vias 62a, 62b, 62c and 62d, as shown in FIG. 1. The conductors 61a to 61d are provided on each surface of the first film 31 to the fourth film 34, and are formed by forming a conductive material on each surface of the first film 31 to the fourth film 34 and then patterning the conductive material. The vias 62a to 62d are formed by burying a conductive material, for example, a part of the constituent material of the conductors 61a to 61d, into via holes formed in the first film 31 to the fourth film 34. The shield portion 60 is constructed by stacking and connecting these conductors 61a to 61d and vias 62a to 62d in the height direction.

A part of the conductors 61a to 61d included in the shield portion 60, here the conductor 61d in the uppermost layer closest to the upper electrode 50, is located at a position higher than the low voltage circuit region 20, specifically, at a position higher than the peripheral elements included in the low voltage circuit region 20. Then, the conductor 61d located higher than the peripheral elements is used as an eaves part 63, and the eaves part 63 protrudes more than the other conductors 61a to 61c on the opposite side with respect to the lower electrode 40 and the upper electrode 50, and covers the upper side of the peripheral elements. Regarding the eaves part 63, it is sufficient that the width thereof, that is, a distance from the end nearer to the lower electrode 40 and the upper electrode 50 to the end farther from the lower electrode 40 and the upper electrode 50, is longer than that of the conductors 61a to 61c other than the eaves part 63. However, it is preferable that the width of the eaves part 63 is 10 μm or more. The eaves part 63 serves to restrict a high electric field from entering the low voltage circuit region 20 from above the shield portion 60 when a high voltage of, for example, 1 kVrms or more is applied to the upper electrode 50, thereby restricting noise and other effects from being caused in the control circuit (not shown). In other words, the eaves part 63 is provided to block the electric field from above the shield portion 60 and protect the low voltage circuit region 20. The eaves part 63 only needs to be able to block the high electric field caused by the upper electrode 50 from entering the low voltage circuit region 20, and the eaves part 63 does not have to be the one closest to the upper electrode 50 among the multiple conductors 61, and multiple eaves parts may be provided.

The shield portion 60 may be disposed at any position. However, the shortest distance L from the upper electrode 50 to the shield portion 60 is set longer than the distance from the upper electrode 50 to the lower electrode 40. The shortest distance L is preferably 13 μm or more.

The second insulating film 70 is an insulating film that is formed around the upper electrode 50 of the first insulating film 30 and covers a part of the outer periphery of the upper electrode 50. The second insulating film 70 is made of an insulating material that can withstand the electric field concentration that occurs near the corners of the upper electrode 50 when a high voltage of, for example, 1 kVrms or more is applied to the upper electrode 50. For example, the second insulating film 70 is made of an insulating material having a insulation breakdown voltage of 10 MV/cm or more, such as TEOS or SiO₂. However, the constituent material of the second insulating film 70 is not limited to these examples. The second insulating film 70 is made of a material having a insulation breakdown voltage higher than at least an insulation breakdown voltage of the third insulating film 80. In other words, the second insulating film 70 restricts the occurrence of insulation breakdown in the third insulating film 80 by withstanding the electric field concentration that occurs when a voltage is applied to the upper electrode 50, while ensuring space between the electric field concentration point and the third insulating film 80 and keeping the third insulating film 80 away from the electric field concentration point.

The second insulating film 70 is formed so as to cover the entire area of the upper electrode 50, and then a portion covering the upper surface 50a of the upper electrode 50 is thinned and flattened by CMP, and an opening portion is formed by etching to expose the upper surface 50a and the slit 51. As shown in FIG. 3, the second insulating film 70 has a thickness t1 at a portion covering the upper electrode 50, that is, a portion located above the upper surface 50a, which is thinner than the thickness of the upper electrode 50, and preferably less than half the thickness of the upper electrode 50. Specifically, for example, when the thickness of the upper electrode 50 is 3.0 μm, the thickness t1 of the second insulating film 70 is 1.5 μm or less, and is preferably 1.3 μm or less. Accordingly, the time required to form the opening portion in the second insulating film 70 for exposing the upper electrode 50 by photolithography etching or the like can be shortened, and the manufacturing cost can be reduced. In addition, as a result of the second insulating film 70 having the thinner thickness t1 at the portion located above the upper surface 50a, the second insulating film 70 has a thickness t2 at a portion covering a side surface 50c of the outer frame portion 53 and t1<t2, as shown in FIG. 3, for example. From the viewpoint of protecting the third insulating film 80 from electric field concentration, which will be described later, t2 is preferably set to 1.3 μm or more. The side surface 50c is a surface of the upper electrode 50 that connects the upper surface 50a and the lower surface 50b. In addition, from the viewpoint of protecting the third insulating film 80 from electric field concentration described later, it is preferable that a thickness t3 of a portion of the second insulating film 70 covering only the first insulating film 30, that is, a portion located outside the upper electrode 50, is 1.3 μm or more. It should be noted that the thickness t3 here is measured based on a position of a lower end of the upper electrode 50.

The second insulating film 70 is formed so as to cover a portion of the side surface 50c of the upper electrode 50, including at least the lower end that is in contact with the first insulating film 30. In the present embodiment, the second insulating film 70 is formed so as to cover, for example, the entire sidewall surface of the outer frame portion 53 of the upper electrode 50 as well as the upper surface 50a of the outer frame portion 53.

The third insulating film 80 is an insulating film that covers a part of the upper electrode 50 and the second insulating film 70. The third insulating film 80 is made of an insulating organic material such as polyimide, and is formed into a predetermined pattern shape by being patterned after being formed into a film by coating. The third insulating film 80 is positioned so as not to come into contact with the high electric field portion that is generated when a high voltage is applied to the upper electrode 50. Therefore, the third insulating film 80 may be made of a material having a lower insulation breakdown voltage than the second insulating film 70. The third insulating film 80 has a thickness such that an upper surface of the third insulating film 80 is located higher than the upper surface 50a of the upper electrode 50 as shown in FIG. 1. For example, when the thickness of the upper electrode 50 is 3.0 μm and the thickness of the second insulating film 70 is 1.3 μm, the thickness of the third insulating film 80 is set to be greater than 1.7 μm. As a result, the electric field generated when a high voltage is applied to the upper electrode 50 is embedded in the second insulating film 70 and the third insulating film 80, and the effect of the electric field on other parts can be reduced.

In the present embodiment, the third insulating film 80 is configured to cover the second insulating film 70, as well as to fill the slit 51 of the upper electrode 50 and cover the end portion of the electrode portion 52 of the upper electrode 50. In other words, the third insulating film 80 has an opening portion that exposes the electrode portion 52 to the outside, and when viewed from above, the third insulating film 80 covers a predetermined area including an area of the upper electrode 50 that is outside the end portion of the electrode portion 52 and the second insulating film 70. Since the third insulating film 80 fills the slit 51, the stress applied to the second insulating film 70 due to thermal cycles can be relaxed. Specifically, the thermal expansion and contraction of the third insulating film 80 due to thermal cycles can be restricted by the portion of the third insulating film 80 that fills the slit 51. As a result, the stress generated in the second insulating film 70 due to the thermal expansion and contraction of the third insulating film 80 can be reduced.

As described above, the signal transmission device including the capacitor coupler constituted by a capacitor configured with the lower electrode 40 and the upper electrode 50 is constructed. In the signal transmission device, when a control circuit (not shown) outputs a control signal to the lower electrode 40, the control signal is transmitted to the upper electrode 50 and then transmitted to an external chip via the wire 90. Accordingly, the drive circuit provided in the external chip can drive the power switching element based on the control signal from the control circuit.

### [Effects of Second Insulating Film]

Next, effects of the second insulating film 70 will be explained, but before that, the occurrence of an insulation breakdown in a capacitor coupler structure according to a comparative example in which the second insulating film 70 is not included and an outer peripheral portion of the upper electrode 50 is covered with an insulating organic material with low insulation breakdown voltage will be explained.

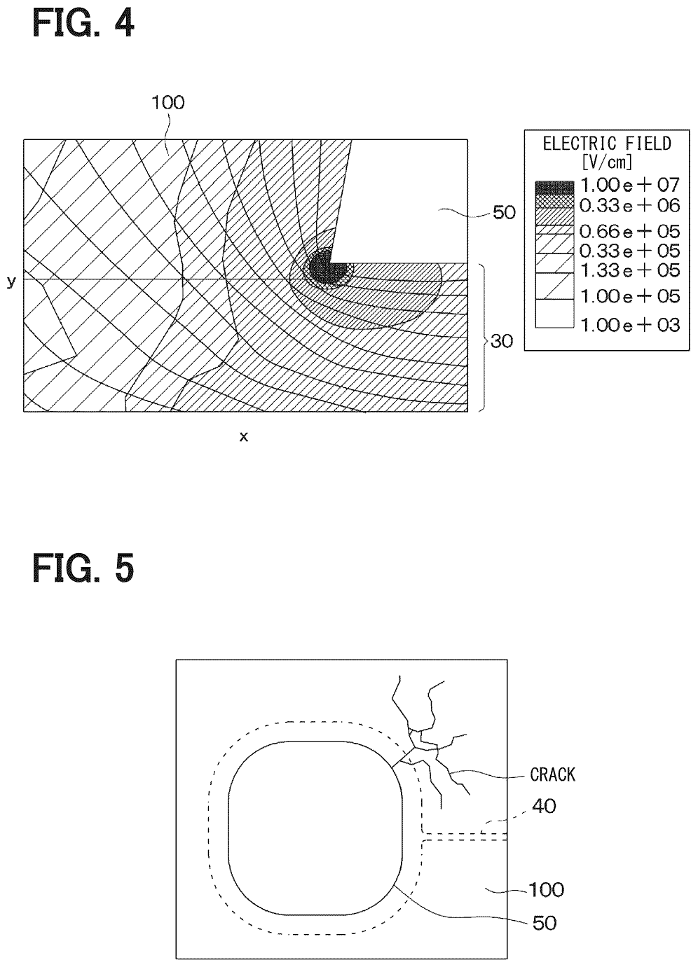

In the capacitor coupler structure of the comparative example, the outer peripheral portion the upper electrode 50 is covered with an organic insulating film 100 made of an insulating organic material such as polyimide, and does not have an insulating film equivalent to the second insulating film 70. In the capacitor coupler structure of the comparative example, a simulation was performed in which a voltage of 2 kVrms was applied to the upper electrode 50. The result of the simulation showed that, for example, as shown in FIG. 4, an electric field was concentrated in the vicinity of a corner of the upper electrode 50 that contacted the first insulating film 30. At this time, in the capacitor coupler structure of the comparative example, a part of the organic insulating film 100 is in contact with a high electric field portion having an electric field strength of about 10 MV/cm. In fact, when a high voltage was repeatedly applied to the upper electrode 50 of a signal transmission device having the capacitor coupler structure of the comparative example, for example, as shown in FIG. 5, cracks occurred starting from a portion of the organic insulating film 100 that was in contact with the outer periphery of the upper electrode 50. It is considered that the cracks occurred because a high electric field exceeding the insulation breakdown voltage of the organic insulating film 100 was applied to the organic insulating film 100, causing damage to the organic insulating film 100 and resulting in an insulation breakdown, that is, a tree breakdown.

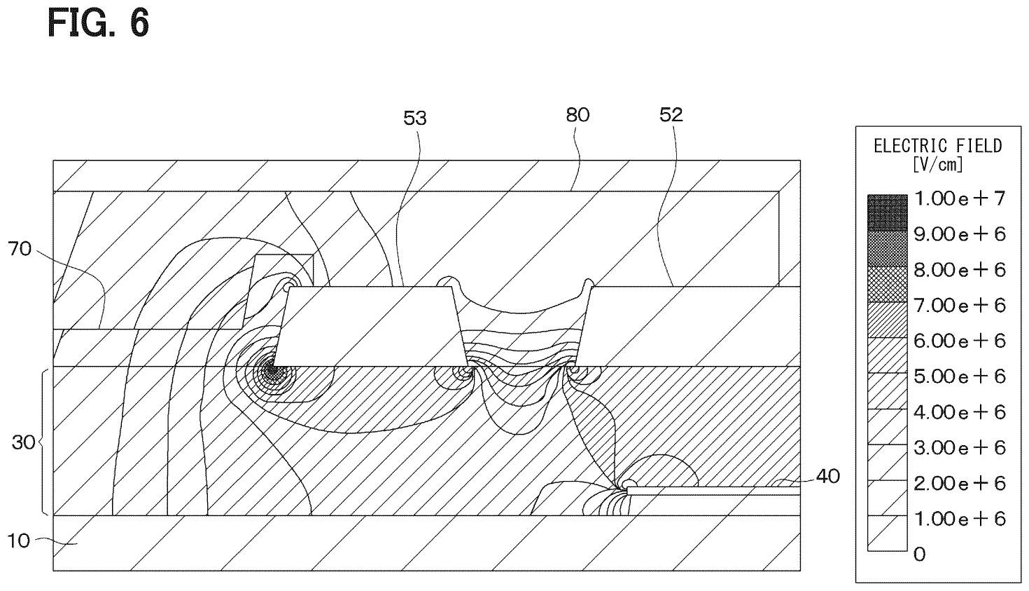

In contrast, in the capacitor coupler structure of the signal transmission device of the present embodiment, the second insulating film 70 made of the insulating material with an insulation breakdown equal to or higher than a predetermined value covers the outer peripheral portion of the upper electrode 50 that is in contact with the first insulating film 30, and the third insulating film 80 is laminated above the second insulating film 70. In the capacitor coupler structure according to the first embodiment, a simulation was performed in the case where a voltage of 2.25 kVrms was applied to the upper electrode 50. As a result, for example, as shown in FIG. 6, corners of the upper electrode 50 being in contact with the first insulating film 30 were high electric field portions. Note that, the outer frame portion 53 shown in FIG. 6 is electrically connected to the electrode portion 52 via the connection portion 54 and has the potential equal to the potential of the electrode portion 52.

Specifically, a high electric field of approximately 10 MV/cm is applied to the corner of the outer frame portion 53 being in contact with the first insulating film 30 and located opposite the slit 51 (hereinafter referred to as an “outer corner”). However, in the capacitor coupler structure according to the first embodiment, the second insulating film 70 made of the material with the insulation breakdown voltage of 10 MV/cm or more abuts against the outer corner, and the third insulating film 80 is disposed above the second insulating film 70. Therefore, no insulation breakdown occurs in the second insulating film 70. Furthermore, since the third insulating film 80, which is made of the insulating organic material having a lower insulation breakdown voltage than the second insulating film 70, is positioned away from the outer corner, the occurrence of a tree breakdown can be restricted.

In addition, at corners of the outer frame portion 53 and the electrode portion 52 located adjacent to the slit 51 and being in contact with the first insulating film 30 (hereinafter referred to as “inner corners”), an electric field was concentrated when a voltage of 2.25 kVrms was applied, but the electric field was 4 MV/cm or less. Therefore, even if the slit 51 is filled with the third insulating film 80, a tree breakdown does not occur in portions of the third insulating film 80 being in contact with the inner corners.

The present embodiment provides the capacitor coupler structure in which the high electric field concentration portion that occurs when a high voltage is applied to the upper electrode 50 is covered with the second insulating film 70 having the high insulation breakdown voltage, and the third insulating film 80 made of the insulating organic material that is suitable for coating is laminated above the second insulating film 70. Therefore, compared to a structure in which the upper electrode 50 is covered with a thick insulating film made only of an insulating material with high insulation breakdown voltage, the time required to form the second insulating film 70 and the third insulating film 80 is shortened, resulting in a structure with reduced manufacturing cost. Furthermore, since the high electric field concentration portion of the upper electrode 50 is covered with the second insulating film 70, and the third insulating film 80 is separated from the high electric field concentration portion, a tree breakdown due to the organic insulating film does not occur. The signal transmission device has the capacitor coupler with a structure that can restrict insulation breakdown in the insulating film covering the outer periphery of the upper electrode, even when a high voltage is applied to the upper electrode, while reducing the manufacturing cost.

Furthermore, the signal transmission device of the present embodiment can achieve the following effects by the following configurations.

When the thickness of the upper electrode 50 is 3.0 μm or more, the occurrence of cracks when the wire 90 is bonded to the upper electrode 50 is restricted, and wire-bonding properties can be ensured.

When the thickness of the portion of the second insulating film 70 covering the upper surface 50a of the upper electrode 50 is less than half the thickness of the upper electrode 50, the amount of etching required when forming the opening portion in the second insulating film 70 to expose the upper electrode 50 is reduced, and the etching process is shortened. Accordingly, the manufacturing cost can be further reduced.

It is preferable that the entire area of the upper surface of the third insulating film 80 is located higher than the upper electrode 50. Accordingly, the electric field generated when a high voltage is applied to the upper electrode 50 can be restricted from leaking outside the upper surface of the third insulating film 80, and unintended electrical effects on the outside can be reduced.

The capacitor coupler structure is preferably disposed at a distance of at least 100 μm away from the outer periphery of the semiconductor substrate 10. For example, when the upper electrode 50 is positioned at a position at least 100 μm away from the outer periphery of the semiconductor substrate 10, the second insulating film 70 is positioned in a region away from the vicinity of the outer periphery and corner portions of the semiconductor substrate 10 where stress is likely to concentrate, thereby reducing the effects of stress. Accordingly, the reliability of the signal transmission device can be further improved.

When the signal transmission device has electrodes (not shown) other than the upper electrode 50 on the first insulating film 30, it is preferable that the second insulating film 70 is not provided on any electrode other than the upper electrode 50. In this case, even when the electrodes (not shown) are covered with a molded resin (not shown), stress caused by the difference in thermal expansion coefficients will not be applied to the second insulating film 70, and cracks caused by the stress will not occur in the second insulating film 70. Accordingly, the reliability of the signal transmission device can be further improved.

### Second Embodiment

A signal transmission device according to a second embodiment will be described.

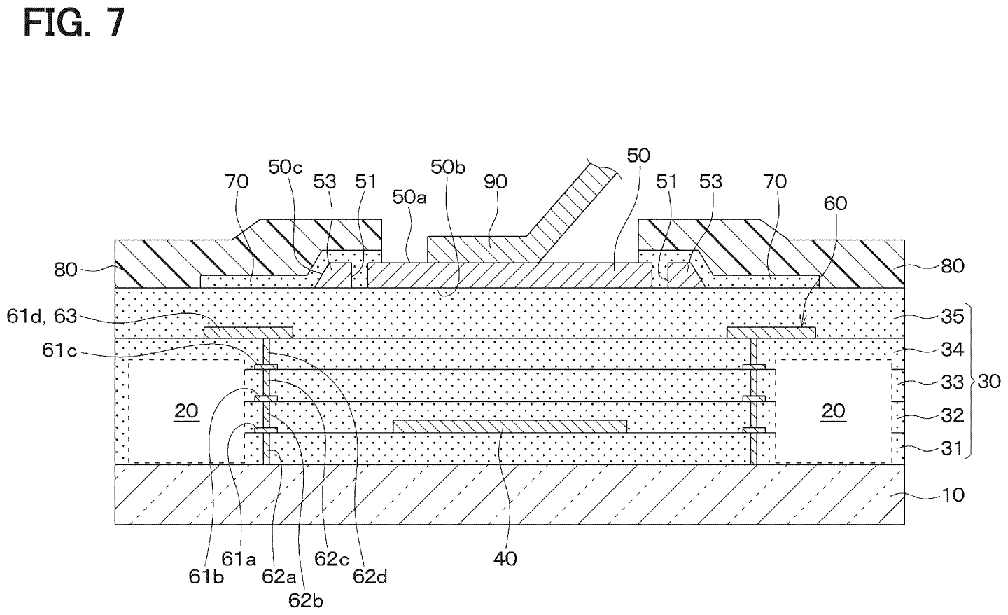

The signal transmission device of the present embodiment differs from the first embodiment in that, as shown in FIG. 7, the second insulating film 70 is also formed in a region inside the outer frame portion 53, and a portion of the second insulating film 70 fills the slit 51. The following describes the difference between the present embodiment and the first embodiment.

In the present embodiment, the second insulating film 70 is formed so as to fill the slit 51 in place of the third insulating film 80. The second insulating film 70 is formed continuously from the side surface 50c, which is the side wall surface of the outer frame portion 53, to an end portion of the upper surface 50a of the electrode portion 52, and fills the slit 51. As a result, even if stress acts on the second insulating film 70 due to stress generated in the third insulating film 80, deformation of the second insulating film 70 is restricted by the portion filling the slit 51, and the stress on the second insulating film 70 is reduced.

The third insulating film 80 is configured to cover, for example, the entire area of the second insulating film 70, and is disposed above the outer frame portion 53 and the electrode portion 52 across the second insulating film 70.

The present embodiment also provides the signal transmission device that can obtain effects similar to the first embodiment.

### Other Embodiments

Although the present disclosure has been made in accordance with the embodiments, it is understood that the present disclosure is not limited to such embodiments and structures. The present disclosure encompasses various modifications and variations within the scope of equivalents. In addition, various combinations and modes, and other combinations and modes including only one element, more elements, or less elements are also within the scope and idea of the present disclosure.

In the first embodiment, the second insulating film 70 may be in a pattern shape that covers only the outer corners of the upper electrode 50. Even with this configuration, the third insulating film 80, which has a lower insulation breakdown voltage than the second insulating film 70, is positioned away from the electric field concentration point of the upper electrode 50, resulting in a signal transmission device that can obtain the same effects as the first embodiment described above. In this case, the second insulating film 70 covers only a partial region including outer corners of the side surface 50c of the upper electrode 50, and the upper surface 50a of the upper electrode 50 is exposed from the second insulating film 70.

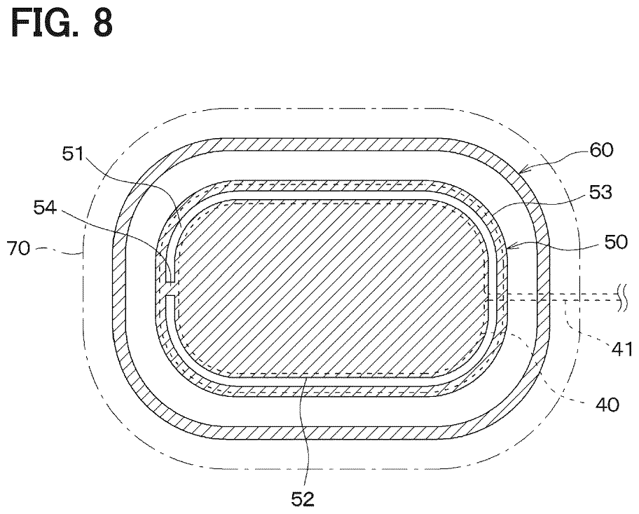

In each of the above embodiments, the lower electrode 40 and the upper electrode 50 do not have to be approximate square, and may be approximate rectangular or an approximate elliptical in top view, for example, as shown in FIG. 8. Even in this case, it is preferable that the electrode portion 52 of the upper electrode 50 has a larger planar size than the lower electrode 40 when viewed from above, and is disposed so as to encompass the entire area of the lower electrode 40.

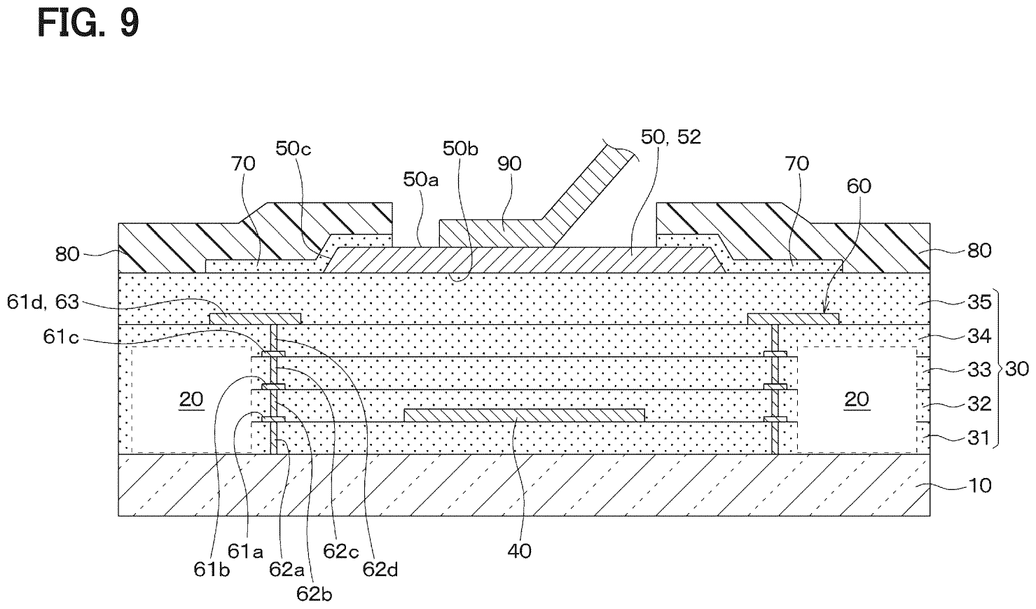

In the first embodiment, the upper electrode 50 may have a configuration without the slit 51, as shown in FIG. 9. Even in this case, the signal transmission device has a structure in which the occurrence of insulation breakdown in the third insulating film 80 is restricted. In this case, the entire area of the upper electrode 50 becomes the electrode portion 52, and a surface of the electrode portion 52 connecting the upper surface 50a and the lower surface 50b becomes the side surface 50c. In this case, the end portion of the upper surface 50a of the upper electrode 50 may be directly covered only by the second insulating film 70, as shown in FIG. 9, with the third insulating film 80 laminated on the second insulating film 70, or may be partially covered by the third insulating film 80 as well.

The constituent element(s) of each of the above embodiments is/are not necessarily essential unless it is specifically stated that the constituent element(s) is/are essential in the above embodiment, or unless the constituent element(s) is/are obviously essential in principle. A quantity, a value, an amount, a range, or the like referred to in the description of the embodiments described above is not necessarily limited to such a specific value, amount, range or the like unless it is specifically described as essential or understood as being essential in principle. Furthermore, a shape, positional relationship or the like of a structural element, which is referred to in the embodiments described above, is not limited to such a shape, positional relationship or the like, unless it is specifically described or obviously necessary to be limited in principle.

What is claimed is:

1. A signal transmission device having a capacitor coupler, comprising:
a semiconductor substrate;
a first insulating film disposed above the semiconductor substrate;
a lower electrode disposed above the semiconductor substrate across a portion of the first insulating film;
an upper electrode disposed opposite the lower electrode across the first insulating film, forming a capacitor together with the lower electrode, and configured to be applied with a voltage higher than a voltage applied to the lower electrode;
a second insulating film disposed above the first insulating film and covering at least a portion in an outer peripheral portion of the upper electrode that is in contact with the first insulating film; and
a third insulating film disposed above the second insulating film and made of an insulating organic material, wherein
the second insulating film is made of a material having a higher insulation breakdown voltage than the third insulating film,
the upper electrode has a thickness of 3.0 μm or more,
a surface of the upper electrode located opposite the first insulating film is defined as an upper surface, a surface of the upper electrode facing the first insulating film is defined as a lower surface, a surface of the upper electrode connecting the upper surface and the lower surface is defined as a side surface, and a thickness of a portion of the second insulating film covering the side surface of the upper electrode is 1.3 μm or more, and
a thickness of a portion of the second insulating film covering the upper surface of the upper electrode is thinner than the thickness of the portion of the second insulating film covering the side surface of the upper electrode.

2. A signal transmission device having a capacitor coupler, comprising:
a semiconductor substrate;
a first insulating film disposed above the semiconductor substrate;
a lower electrode disposed above the semiconductor substrate across a portion of the first insulating film;
an upper electrode disposed opposite the lower electrode across the first insulating film, forming a capacitor together with the lower electrode, and configured to be applied with a voltage higher than a voltage applied to the lower electrode;
a second insulating film disposed above the first insulating film and covering at least a portion in an outer peripheral portion of the upper electrode that is in contact with the first insulating film; and
a third insulating film disposed above the second insulating film and made of an insulating organic material, wherein
the second insulating film is made of a material having a higher insulation breakdown voltage than the third insulating film,
the upper electrode has a thickness of 3.0 μm or more,
a surface of the upper electrode located opposite the first insulating film is defined as an upper surface, a surface of the upper electrode facing the first insulating film is defined as a lower surface, a surface of the upper electrode connecting the upper surface and the lower surface is defined as a side surface, and a thickness of a portion of the second insulating film covering the side surface of the upper electrode is 1.3 μm or more, and
when viewed from a normal direction to a surface of the semiconductor substrate on which the first insulating film is disposed, an entire area of the lower electrode is disposed inside an outer periphery of the upper electrode.

3. A signal transmission device having a capacitor coupler, comprising:
a semiconductor substrate;
a first insulating film disposed above the semiconductor substrate;
a lower electrode disposed above the semiconductor substrate across a portion of the first insulating film;
an upper electrode disposed opposite the lower electrode across the first insulating film, forming a capacitor together with the lower electrode, and configured to be applied with a voltage higher than a voltage applied to the lower electrode;
a second insulating film disposed above the first insulating film and covering at least a portion in an outer peripheral portion of the upper electrode that is in contact with the first insulating film; and
a third insulating film disposed above the second insulating film and made of an insulating organic material, wherein
the second insulating film is made of a material having a higher insulation breakdown voltage than the third insulating film,
the upper electrode has a slit in a vicinity of an outer periphery of the upper electrode, and
the slit extends along the outer periphery of the upper electrode.

4. The signal transmission device according to claim 3, wherein
a portion of the upper electrode located outside the slit has a potential equal to or independent of a potential of a portion of the upper electrode located inside the slit.

5. The signal transmission device according to claim 3, wherein
the upper electrode has a thickness of 3.0 μm or more.

6. The signal transmission device according to claim 5, wherein
a portion of the second insulating film located outside the upper electrode has a thickness of 1.3 μm or more.

7. The signal transmission device according to claim 5, wherein
a surface of the upper electrode located opposite the first insulating film is defined as an upper surface, a surface of the upper electrode facing the first insulating film is defined as a lower surface, a surface of the upper electrode connecting the upper surface and the lower surface is defined as a side surface, and a thickness of a portion of the second insulating film covering the side surface of the upper electrode is 1.3 μm or more.

8. The signal transmission device according to claim 1, wherein
an entire area of an upper surface of the third insulating film is located higher than the upper surface of the upper electrode.

9. The signal transmission device according to claim 1, wherein
the thickness of the portion of the second insulating film covering the upper surface of the upper electrode is half or less of the thickness of the upper electrode.

10. The signal transmission device according to claim 1, wherein
the second insulating film covers a portion of the side surface of the upper electrode including a lower end that is in contact with the first insulating film, and
the upper surface of the upper electrode is exposed from the second insulating film.

11. The signal transmission device according to claim 1, wherein
the upper electrode is disposed at a position 100 μm or more away from an outer periphery of the semiconductor substrate.

12. The signal transmission device according to claim 1, wherein
the second insulating film and the third insulating film cover only a portion of the upper electrode among a plurality of electrodes disposed above the first insulating film.
